(19) United States
(12) Patent Application Publication
(10) Pub. No.: US 2025/0368838 A1
(43) Pub. Date: Dec. 4, 2025

(54) EPOXY RESIN COMPOSITION FOR ENCAPSULATING MULTICHIP PACKAGE AND MULTICHIP PACKAGE ENCAPSULATED USING THE SAME

(71) Applicant: SAMSUNG SDI CO., LTD., Yongin-si (KR)

(72) Inventor: Kyoung Chul BAE, Suwon-si (KR)

(21) Appl. No.: 19/208,671

(22) Filed: May 15, 2025

(30) Foreign Application Priority Data
Jun. 3, 2024 (KR) 10-2024-0072126

(51) Int. Cl. C09D 7/63; C08G 59/24; C08G 59/62; C08K 5/00; C09D 163/00; H01L 23/29

(52) U.S. Cl. CPC C09D 7/63; C08G 59/245; C08G 59/621; C09D 163/00; C08K 5/0091; H01L 23/295

(57) ABSTRACT

An epoxy resin composition for encapsulation of multichip packages and a multichip package encapsulated using the epoxy resin composition for encapsulation of multichip packages, epoxy resin composition for encapsulation of multichip packages including an epoxy resin, a curing agent, an inorganic filler, a curing catalyst; and a first additive, wherein the first additive includes zinc cyanurate.

### CROSS-REFERENCE TO RELATED APPLICATION

The present application claims priority and the benefit of Korean Patent Application No. 10-2024-0072126, filed on Jun. 3, 2024, in the Korean Intellectual Property Office, the entire disclosure of which is incorporated herein by reference.

### 1. Field

Embodiments relate to an epoxy resin composition for encapsulation of multichip packages and a multichip package encapsulated using the same.

### 2. Description of the Related Art

The integration density of semiconductor devices has been steadily increasing, leading to rapid advancements in miniaturization of interconnects, larger device sizes, and multilayer interconnects. In response to demand for high-density mounting on printed circuit boards, that is, high-density surface mounting, miniaturization and thinning of semiconductor packages serving to protect semiconductor devices from external environments continues to accelerate.

### SUMMARY

Embodiments are directed to an epoxy resin composition for encapsulation of multichip packages, the epoxy resin composition including an epoxy resin, a curing agent, an inorganic filler, a curing catalyst, and a first additive, wherein the first additive includes zinc cyanurate.

The zinc cyanurate may be included in the epoxy resin composition in an amount of 0.01 wt % to 15 wt %, based on a total weight of the epoxy resin composition.

The zinc cyanurate may include a compound represented by Formula 5:

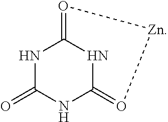

The epoxy resin may include a biphenyl type epoxy resin, a phenol aralkyl type epoxy resin, or a halogenated epoxy resin.

The curing agent may include a Xylok type phenol resin, a phenol aralkyl type phenol resin, or a phenol novolac type phenol resin.

The epoxy resin composition may include, based on a total amount of the epoxy resin composition, 2 wt % to 17 wt % of the epoxy resin, 0.1 wt % to 13 wt % of the curing agent, 50 wt % to 95 wt % of the inorganic filler, 0.01 wt % to 10 wt % of the curing catalyst, and 0.01 wt % to 15 wt % of the first additive.

The embodiments may be realized by providing a multichip package encapsulated using the epoxy resin composition according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not an exclusive term, e.g., “A or B” would include A, B, or A and B.

Herein, the singular forms “a”, “an”, and “the” are intended to include the plural forms as well, unless the context specifically indicates otherwise.

As used herein to represent a specific numerical range, “X to Y” means “greater than or equal to X and less than or equal to Y”.

In accordance with one aspect of the present disclosure, an epoxy resin composition for encapsulation of multichip packages may include, e.g., an epoxy resin, a curing agent, an inorganic filler, a curing catalyst, and a first additive, wherein the first additive may include zinc cyanurate.

### Epoxy Resin

The epoxy resin may include at least one epoxy resin containing at least two epoxy groups in a molecular structure thereof. In an implementation, the epoxy resin may include, e.g., bisphenol A type epoxy resins, bisphenol F type epoxy resins, phenol novolac type epoxy resins, tert-butyl catechol type epoxy resins, naphthalene type epoxy resins, glycidyl amine type epoxy resins, cresol novolac type epoxy resins, biphenyl type epoxy resins, phenol aralkyl type epoxy resins, linear aliphatic epoxy resins, cycloaliphatic epoxy resins, heterocyclic epoxy resins, spirocyclic epoxy resins, cyclohexanedimethanol type epoxy resins, trimethylol type epoxy resins, and halogenated epoxy resins including brominated epoxy resins or the like. These epoxy resins may be used alone or as a mixture thereof.

In an implementation, the epoxy resin may include, e.g., a biphenyl type epoxy resin, a phenol aralkyl type epoxy resin, and a halogenated epoxy resin. In an implementation, the epoxy resin may include a mixture of a biphenyl type epoxy resin, a phenol aralkyl type epoxy resin, or a halogenated epoxy resin.

In an implementation, the biphenyl type epoxy resin may include, e.g., a compound represented by Formula 1.

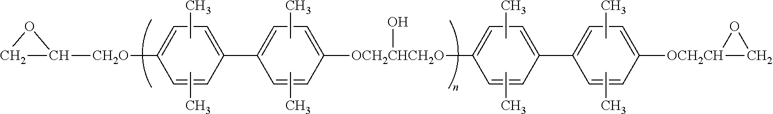

In Formula 1, n may be, e.g., an integer of 1 to 7.

In an implementation, the phenol aralkyl type epoxy resin may include, e.g., a compound represented by Formula 2.

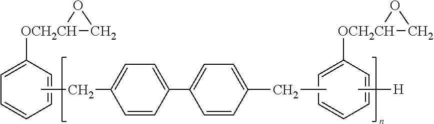

In Formula 2, n may be, e.g., an integer of 1 to 7.

In an implementation, the biphenyl type epoxy resin may be included in the epoxy resin in an amount of 40 wt % or more, e.g., 45 wt % or more, based on the total weight of the epoxy resin. The biphenyl type epoxy resin may be used alone or in the form of an adduct prepared by an addition reaction of the compound represented by Formula 1.

The epoxy resin may be included in the epoxy resin composition in an amount of 2 wt % to 17 wt %, e.g., 3 wt % to 15 wt %, 2 wt % to 10 wt %, or 3 wt % to 12 wt %, based on a total weight of the epoxy resin composition. Maintaining the amount of epoxy resin within this range may help ensure that the composition may secure curability.

### Curing Agent

The curing agent may include, e.g., novolac type phenol resins, cresol novolac type phenol resins, polyfunctional phenol resins, phenol aralkyl type phenol resins, phenol novolac type phenol resins, Xylok type phenol resins, naphthol type phenol resins, terpene type phenol resins, dicyclopentadiene phenol resins, novolac type phenol resins synthesized from bisphenol A or resol, polyhydric phenol compounds including, e.g., tris(hydroxyphenyl)methane, dihydroxybiphenyl, or the like, acid anhydrides including maleic anhydride, phthalic anhydride, or the like, or aromatic amines including, e.g., metaphenylenediamine, diaminodiphenylmethane, diaminodiphenylsulfone, or the like. These curing agents may be used alone or as a mixture thereof.

In an implementation, the curing agent may include, e.g., a phenol curing agent which may help provide improved properties in terms of moldability during molding of a semiconductor or multichip package, moisture resistance, heat resistance, and preservability.

In an implementation, the curing agent may include, e.g., a Xylok type phenol resin, a phenol aralkyl type phenol resin, or a phenol novolac type phenol resin. In an implementation, the curing agent may include, e.g., a mixture of a Xylok type phenol resin, a phenol aralkyl type phenol resin, or a phenol novolac type phenol resin. In an implementation, the Xylok type phenol resin may include, e.g., a compound

represented by Formula 3.

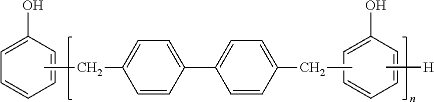

In Formula 3, n may be, e.g. an integer of 1 to 7.

In an implementation, the phenol aralkyl type phenol resin may include, e.g., a compound represented by Formula 4.

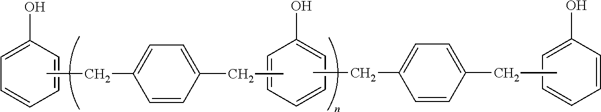

In Formula 4, n may be, e.g., an integer of 1 to 7.

In an implementation, the phenol aralkyl type phenol resin may be included in the curing agent in an amount of 20 wt % or more, e.g., 25 wt % or more, based on the total weight of the curing agent.

The curing agent may be included in the epoxy resin composition in an amount of 0.1 wt % to 13 wt %, e.g., 0.1 wt % to 10 wt % or 0.5 wt % to 7 wt %, based on the total weight of the epoxy resin composition. Maintaining the amount of curing agent in these ranges may help ensure that the composition may secure curability.

To meet the requirements related to mechanical properties and moisture resistance reliability of the epoxy resin composition, it may be desirable that a chemical equivalent weight ratio of the curing agent to the epoxy resin be in the range of 0.5 to 1.5, e.g., 0.8 to 1.2.

### Inorganic Filler

The inorganic filler may help improve mechanical properties of the epoxy resin composition while reducing internal stress of the epoxy resin composition.

The inorganic filler may include, e.g., fused silica, crystalline silica, calcium carbonate, magnesium carbonate, alumina, magnesia, clay, talc, calcium silicate, titanium oxide, antimony oxide, or glass fiber.

In an implementation, the inorganic filler may include silica.

The silica may include, e.g., fused silica or crystalline silica. The silica may include, e.g., fused silica having a low coefficient of linear expansion to reduce internal stress of the epoxy resin composition. Here, fused silica may refer to, e.g., amorphous silica having a true specific gravity of 2.3 or less and may include amorphous silica that is prepared by melting crystalline silica or may be synthesized from various raw materials. In an implementation, it may be desirable that spherical fused silica having, e.g., an average particle diameter (D₅₀) of 5 μm to 30 μm be included in the inorganic filler in an amount of 40 wt % to 100 wt %, based on a total weight of the inorganic fillers. In an implementation, the silica may include, e.g., a silica mixture including 50 wt % to 99 wt % of spherical fused silica having an average particle diameter (D₅₀) of 5 μm to 30 μm and 1 wt % to 50 wt % of spherical fused silica having an average particle diameter of 0.001 μm to 1 μm, based on a total weight of the silica. In an implementation, the maximum particle diameter of the inorganic fillers may be, e.g., adjusted to any one of 45 μm, 55 μm, or 75 μm, depending on the intended applications thereof. Here, “average particle diameter (D₅₀)” may be a typical particle diameter measure known in the art and may refer to a particle diameter of the inorganic fillers corresponding to 50 vol % when the inorganic fillers are distributed in order from smallest to largest in terms of volume.

The silica may be included in the inorganic filler in an amount of 40 wt % or more, e.g., 60 wt % or more, based on the total weight of the inorganic fillers.

The content of the inorganic fillers in the composition may be varied depending on properties required for the composition, e.g., thermal conductivity, moldability, low stress, or strength at high temperature. In some embodiments, the inorganic fillers may be included in the epoxy resin composition in an amount of 50 wt % to 95 wt %, e.g., 70 wt % to 95 wt % or 85 wt % to 95 wt %, based on the total weight of the epoxy resin composition. Maintaing the amount of the inorganic filler in this range may help ensure that the epoxy resin composition may have good properties in terms of flame retardancy, fluidity, and reliability.

### Curing Catalyst

The curing catalyst may include, e.g., a tertiary amine compound, an organometallic compound, an organophosphorus compound, an imidazole compound, or a boron compound. The tertiary amine compound may include, e.g., benzyldimethylamine, triethanolamine, triethylenediamine, diethylaminoethanol, tri(dimethylaminomethyl)phenol, 2,2-(dimethylaminomethyl)phenol, 2,4,6-tris(diaminomethyl)phenol, tri-2-ethyl hexanoate, and the like. The organometallic compound may include, e.g., chromium acetylacetonate, zinc acetylacetonate, nickel acetylacetonate, or the like. The organophosphorus compound may include, e.g., triphenylphosphine, tris-4-methoxyphosphine, triphenylphosphine-triphenylborane, a triphenylphosphine-1,4-benzoquinone adduct, or the like. The imidazole compound may include, e.g., 2-methylimidazole, 2-phenylimidazole, 2-aminoimidazole, 2-methyl-1-vinylimidazole, 2-ethyl-4-methylimidazole, 2-heptadecyl imidazole, or the like. The boron compound may include, e.g., triphenylphosphine tetraphenyl borate, a tetraphenylboron salt, trifluoroborane-n-hexylamine, trifluoroborane monoethylamine, tetrafluoroborane triethylamine, tetrafluoroborane amine, or the like. In an implementation, 1,5-diazabicyclo[4.3.0]non-5-ene (DBN), 1,8-diazabicyclo[5.4.0]undec-7-ene (DBU), or a phenol novolac resin salt may be used as the curing catalyst.

The curing catalyst may be included in the form of an adduct prepared by pre-reacting the curing catalyst with the epoxy resin or the curing agent.

The curing catalyst may be included in the epoxy resin composition in an amount of 0.01 wt % to 10 wt %, e.g., 0.01 wt % to 5 wt %, based on the total weight the epoxy resin composition. Maintaining the amount of curing catalyst within these ranges may help ensure that the curing catalyst may promote curing of the composition without sacrificing fluidity of the composition.

### First Additive

The first additive may help reduce the moisture absorption rate of the composition, thereby helping suppress void defects in a multichip package and thus helping improve crack resistance and reliability of the multichip package.

The first additive may include, e.g., zinc cyanurate. Generally, triazine-2,4,6-triol, which is an enol form of cyanuric acid, and triazine-2,4,6-trione, which is a keto form of cyanuric acid, are known as cyanuric acid. However, since enol and keto forms are tautomers of each other, the term cyanuric acid may include not only triazine-2,4,6-triol as an enol form, but also as triazine-2,4,6-trione as a keto form.

The zinc cyanurate may be a compound in which zinc is coordination-bonded to cyanuric acid and may have, e.g., a structure represented by Formula 5.

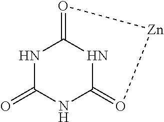

According to one embodiment, the zinc cyanurate may be provided in the form of a salt.

In an implementation, the provided zinc cyanurate may have an index of refraction of, e.g., 1.4 to 2.1 and may be in a solid phase at ambient temperature. In an implementation, the zinc cyanurate may have a water content of 1.5% or less and a density of 2.0 g/cm³ to 4.0 g/cm³.

The first additive, i.e., the zinc cyanurate, may be included in the epoxy resin composition in an amount of 0.01 wt % to 15 wt %, based on a total amount of the epoxy resin composition. Maintaining the amount of the first additive within this range may help ensure that first additive may help reduce the moisture absorption rate of the composition, thereby helping improve the reliability of a multichip package. In an implementation, the zinc cyanurate may be included in the epoxy resin composition in an amount of 0.1 wt % to 5 wt %, e.g., 0.1 wt % to 3 wt %, or 0.1 wt % to 3 wt %, based on a total amount of the epoxy resin composition.

### Second Additive

The epoxy resin composition may further include, e.g., suitable additives used in epoxy resin compositions for encapsulation of multichip packages or semiconductor devices, as a second additive. In an implementation, the second additive may include, e.g., a coupling agent, a release agent, a colorant, a stress relieving agent, a flame retardant, a crosslinking enhancer, or a leveling agent.

The coupling agent may help increase interfacial strength between the epoxy resin and the inorganic fillers through reaction with the epoxy resin and the inorganic fillers and may include, e.g., a silane coupling agent. The silane coupling agent may include, e.g., any suitable silane coupling agent that may help increase interfacial strength between the epoxy resin and the inorganic fillers through reaction with the epoxy resin and the inorganic fillers. The silane coupling agent may include, e.g., epoxysilane, aminosilane, ureidosilane, mercaptosilane, an alkylsilane, or the like. In an implementation, the coupling agent may include, e.g., a mixture of mercaptosilane, an alkylsilane, or epoxysilane.

These coupling agents may be used alone or in combination thereof. The coupling agent may be included in the epoxy resin composition in an amount of 0.01 wt % to 5 wt %, e.g., 0.05 wt % to 3 wt %, based on a total weight of the epoxy resin composition. Maintaining the amount of the coupling agent in this range may help ensure that a cured product of the epoxy resin composition may have enhanced strength.

The release agent may include e.g., paraffin wax, ester wax, higher fatty acids, metal salts of higher fatty acids, natural fatty acids, or metal salts of natural fatty acids. The release agent may be included in the epoxy resin composition in an amount of 0.1 wt % to 1 wt %, based on a total weight of the epoxy resin composition.

The colorant may include carbon black. The colorant may be included in the epoxy resin composition in an amount of 0.1 wt % to 1 wt %, based on a total weight of the epoxy resin composition.

The stress relieving agent may include, e.g., modified silicone oils, silicone elastomers, silicone powders, and silicone resins. As the modified silicone oil, a silicone polymer having good heat resistance may be preferred. The modified silicone oil may include, e.g., a silicone oil mixture including silicone oil including, e.g., an epoxy functional group, silicone oil containing an amine functional group, silicone oil containing a carboxyl functional group, or a combination thereof, wherein the silicone oil mixture may be included in the epoxy resin composition in an amount of 0.05 wt % to 1.5 wt %, based on the total weight of the epoxy resin composition. If the content of the silicone oil exceeds 1.5 wt %, surface contamination may occur easily and lengthy resin bleed may be encountered. If the content of the silicone oil is less than 0.05 wt %, there may be a problem in that sufficiently low modulus of elasticity may not be obtained. In an implementation, silicone powder having, e.g., a median particle diameter of 15 μm or less may be particularly preferred in that the powder may not deteriorate moldability. The silicone powder may be included in the epoxy resin in an amount of 0.05 wt % to 5 wt %, based on the total weight of the epoxy resin composition.

The stress relieving agent may be included in the epoxy resin composition in an amount of 0.1 wt % to 6.5 wt %, e.g., 1 wt % or less or 0.1 wt % to 1 wt %, based on the total weight of the epoxy resin composition.

The flame retardant may include, e.g., antimony trioxide or phosphorus flame retardants. The flame retardant may be included in the epoxy resin composition in an amount of 2 wt % or less, e.g., 1.5 wt % or less or 0.1 wt % to 1 wt %, based on the epoxy resin composition.

The second additive may be included in the epoxy resin composition in an amount of 0.1 wt % to 5 wt %, e.g., 0.1 wt % to 3 wt %, based on a total weight of the epoxy resin composition.

In an implementation, the epoxy resin composition may be prepared by, e.g., uniformly mixing the aforementioned components in a Henschel mixer or a Lödige mixer, melt-kneading the mixture in a roll mill or a kneader at 90° C. to 120° C., and subjecting the resulting product to cooling and pulverization.

In accordance with another aspect of the present disclosure, a multichip package may be encapsulated using the epoxy resin composition for encapsulation of multichip packages according to the present disclosure. The multichip package may be encapsulated with the epoxy resin composition by any suitable method known in the art, such as transfer molding, injection molding, casting, or compression molding. In one embodiment, the multichip package may be encapsulated with the epoxy resin composition by low-pressure transfer molding. In another embodiment, the multichip package may be encapsulated with the epoxy resin composition by compression molding.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Details of components used in the Examples and Comparative Examples were as follows:
(A) Epoxy resin
(A1) A biphenyl type epoxy resin (epoxy equivalent weight: 190 g/eq, YX-4000H (JER) Mitsubishi Chemical Co., Ltd.)
(A2) A phenol aralkyl type epoxy resin (epoxy equivalent weight: 270 g/eq, NC-3000, Nippon Kayaku Co., Ltd.)
(B) Curing agent
(B1) A Xylok type phenol resin (hydroxyl equivalent weight: 175 g/eq, MEH-7800-4S, Meiwa Chemical Co., Ltd.)
(B2) A phenol aralkyl type phenol resin (hydroxyl equivalent weight: 200 g/eq, MEH-7851-SS, Meiwa Chemical Co., Ltd.)
(B3) A phenol novolac type phenol resin (hydroxyl equivalent weight: 100 g/eq, H-4, Meiwa Chemical Co., Ltd.)
(C) Curing catalyst: Triphenyl phosphine (Hokko Chemical Co., Ltd.)
(D) Inorganic filler: A mixture of spherical fused alumina having an average particle diameter (D₅₀) of 20 μm and spherical fused alumina having an average particle diameter (D₅₀) of 0.5 μm (weight ratio: 9:1)
(E) Zinc cyanurate (water content: 0.9 wt %, density: 3.0 g/cm³, index of refraction: 1.7, Starfine, Nissan Chemical Co., Ltd.)
(F) Coupling agent
(F1) γ-glycidoxypropyltrimethoxysilane (epoxysilane)
(F2) Mercaptopropyltrimethoxysilane (mercaptosilane)
(F3) Methyltrimethoxysilane (alkylsilane)
(G) Antimony trioxide
(H) Silicone powder
(I) Carbon Black (MA-600B, Mitsubishi Chemical Co., Ltd.)
(J) Carnauba wax

### Examples 1 to 4 and Comparative Examples 1 to 3

The aforementioned components were uniformly mixed in amounts shown in Table 1 (unit: parts by weight) in a Henschel mixer (KSM-22, KEUM SUNG MACHINERY Co., Ltd.) at a temperature of 25° C. to 30° C. for 30 minutes. Thereafter, the mixture was subjected to melt-kneading in a continuous kneader at a temperature of up to 110° C. for 30 minutes, cooled to a temperature of 10° C. to 15° C., and pulverized, thereby preparing an epoxy resin composition for encapsulation of multichip packages. In Table 1, “-” means that a corresponding component was not used.

Each of the epoxy resin compositions prepared in the Examples and Comparative Examples was evaluated as to the following properties. Results are shown in Table 2.
(1) Fluidity (spiral flow length, unit: inch): Using a low-pressure transfer molding machine, each of the prepared epoxy resin compositions was injected into a mold for measurement of fluidity under conditions of a mold temperature of 175° C., a load of 70 kgf/cm², an injection pressure of 9 MPa, and a curing time of 90 seconds in accordance with EMMI-1-66, followed by measurement of flow length. A greater flow length indicates better fluidity.
(2) Flexural strength (unit: kgf/mm²) and flexural modulus (unit: kgf/mm²): In accordance with ASTM D-790, a standard specimen (size: 125 mm×12.6 mm×6.4 mm (length×width×thickness)) was prepared from each of the prepared epoxy resin compositions and was cured at 175° C. for 4 hours, followed by measurement of toughness of the specimen at 260° C. using a Universal Testing Machine (UTM).
(3) Moisture absorption rate (unit: weight %): Each of the epoxy resin compositions prepared in the Examples and Comparative Examples was molded under conditions of a mold temperature of 170° C. to 180° C., a clamp pressure of 70 kg/cm2, a transfer pressure of 1,000 psi, a transfer rate of 0.5 cm/s to 1 cm/s, and a curing time of 120 sec, thereby obtaining a disc-shaped cured specimen (diameter: 50 mm, thickness: 1.0 mm). The obtained specimen was subjected to post-mold cure (PMC) in an oven at a temperature of 170° C. to 180° C. for 4 hours and then left at 85° C. and 85% RH for 168 hours. Changes in weight of the specimen before and after moisture absorption were measured. Moisture absorption rate was calculated according to Equation 1:

$$Moisture absorption rate ( \% ) = [ ( Weight of the specimen after moisture absorption ‐ Weight of the specimen before moisture absorption ) / ( Weight of the specimen before moisture absorption ) ] \times 100$$

(4) Reliability (unit: number): Each of the prepared compositions was subjected to preconditioning treatment and a thermal shock test of 1,000 cycles, followed by evaluation of the presence of cracks by scanning acoustic tomography (SAT), which is a non-destructive testing method.

### <Preconditioning Treatment>

A multichip package manufactured using each of the prepared epoxy resin compositions was subjected to preconditioning treatment in which a process of leaving the package at 85° C. and 85% RH for 96 hours, followed by IR reflow at 260° C. for 10 sec was repeated three times. Thereafter, the presence of cracks in the multichip package was evaluated. When cracks occurred in the multichip package, a thermal shock test described below was not conducted.

### <Thermal Shock>

A multichip package subjected to preconditioning treatment was subjected to a total of 1,000 cycles of thermal shock test (1 cycle being defined as leaving the package at −65° C. for 10 minutes, at 25° C. for 5 minutes, and at 150° C. for 10 minutes). Thereafter, the presence of internal and external cracks was evaluated by scanning acoustic tomography (SAT), which is a non-destructive testing method.

### <Reliability>

For a reliability test, each of the prepared compositions was molded at 175° C. for 70 sec using a multi plunger system (MPS) molding machine, followed by post-mold cure at 175° C. for 2 hours, thereby manufacturing a multichip package with four semiconductor chips stacked vertically through an organic bonding film. Reliability was determined by the degree of cracking in the package after the thermal shock test.
(5) Moldability: With respect to multichip packages used in the reliability test, the number of multichip packages having void defects was checked with the naked eye.

TABLE 1

| | | Example | | | | Comparative Example | | |
|---|---|---|---|---|---|---|---|---|
| | | 1 | 2 | 3 | 4 | 1 | 2 | 3 |
| (A) | (A1) | 3.05 | 3.05 | 3.05 | 3.05 | 3.05 | 3.05 | 3.05 |
| | (A2) | 2.72 | 2.72 | 2.72 | 2.72 | 2.72 | 2.72 | 2.72 |
| (B) | (B1) | 2.64 | 2.64 | 2.64 | 2.64 | 2.64 | 2.64 | 2.64 |
| | (B2) | 1.44 | 1.44 | 1.44 | 1.44 | 1.44 | 1.44 | 1.44 |
| | (B3) | 1.00 | 1.00 | 1.00 | 1.00 | 1.00 | 1.00 | 1.00 |
| (C) | | 0.17 | 0.17 | 0.17 | 0.17 | 0.17 | 0.17 | 0.17 |
| (D) | | 87 | 87 | 87 | 87 | 87 | 87 | 87 |
| (E) | | 0.56 | 0.76 | 0.56 | 0.4 | 0 | 0 | 0 |
| (F) | (F1) | 0 | 0 | 0.08 | 0.16 | 0.16 | 0.8 | 0.08 |
| | (F2) | 0.08 | 0 | 0.12 | 0.16 | 0.04 | 0 | 0.68 |
| | (F3) | 0.16 | 0.04 | 0.04 | 0.08 | 0.6 | 0 | 0.04 |

| | | | | | | | |
|---|---|---|---|---|---|---|---|
| (G) | 0.50 | 0.50 | 0.50 | 0.50 | 0.50 | 0.50 | 0.50 |
| (H) | 0.30 | 0.30 | 0.30 | 0.30 | 0.30 | 0.30 | 0.30 |
| (I) | 0.22 | 0.22 | 0.22 | 0.22 | 0.22 | 0.22 | 0.22 |
| (J) | 0.16 | 0.16 | 0.16 | 0.16 | 0.16 | 0.16 | 0.16 |
| Total | 100 | 100 | 100 | 100 | 100 | 100 | 100 |

TABLE 2

| | | Example | | | | Comparative Example | | |
|---|---|---|---|---|---|---|---|---|
| | | 1 | 2 | 3 | 4 | 1 | 2 | 3 |
| Fluidity | | 47 | 52 | 50 | 49 | 48 | 47 | 46 |
| Flexural strength | | 1.4 | 1.5 | 1.5 | 1.5 | 1.1 | 1.2 | 1.3 |
| Flexural modulus | | 80 | 82 | 68 | 61 | 78 | 85 | 73 |
| Moisture absorption rate | | 0.193 | 0.187 | 0.195 | 0.193 | 0.244 | 0.256 | 0.251 |
| Reliability | Number of | 0 | 0 | 0 | 0 | 27 | 24 | 19 |
| | packages | | | | | | | |
| | having | | | | | | | |
| | cracks after | | | | | | | |
| | thermal | | | | | | | |
| | shock | | | | | | | |
| | Number of | 0 | 0 | 0 | 0 | 103 | 152 | 134 |
| | packages | | | | | | | |
| | having | | | | | | | |
| | delamination | | | | | | | |
| | Number of | 240 | 240 | 240 | 240 | 240 | 240 | 240 |
| | tested | | | | | | | |
| | packages | | | | | | | |
| Moldability | Number of | 0 | 0 | 0 | 0 | 3 | 1 | 2 |
| | packages | | | | | | | |
| | having void | | | | | | | |
| | defects | | | | | | | |
| | Number of | 256 | 256 | 256 | 256 | 256 | 256 | 256 |
| | tested | | | | | | | |
| | packages | | | | | | | |

As can be seen from Table 2, the epoxy resin compositions for encapsulation of multichip packages according to the Examples were able to suppress void defects during molding of a multichip package, thereby preventing cracking of the multichip package and thus providing improved moldability and reliability.

By way of summation and review, semiconductor apparatuses with large-sized semiconductor devices encapsulated in a small, thin package may be prone to failure, e.g., cracking of the package and corrosion of an aluminum pad due to thermal stress caused by changes in external temperature and humidity. To address the cracking of semiconductor packages, there may be a growing need for reliable epoxy resin molding compounds.

Recently, to provide smaller, thinner, and higher-performing semiconductor devices, multichip packages, in which multiple semiconductor chips are stacked vertically, have emerged as a promising solution. In these packages, die attach films (DAFs) may be used to bond the chips together. However, in terms of reliability, this bonding method may have disadvantages when compared to other methods that use a metal-based paste, which may be a sort of chip adhesive, to bond a single semiconductor chip to a metal pad.

It is an aspect of the present disclosure to provide an epoxy resin composition for encapsulation of multichip packages that may help suppress void defects during molding of a multichip package.

In accordance with one aspect of the present disclosure, an epoxy resin composition for encapsulation of multichip packages may be provided.

Embodiments of the present disclosure may provide an epoxy resin composition for encapsulation of multichip packages that may help suppress void defects during molding of a multichip package, thereby preventing cracking of the multichip package and thus providing improved moldability and reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for encapsulation of multichip packages, the epoxy resin composition comprising:
an epoxy resin;
a curing agent;
an inorganic filler;
a curing catalyst; and
a first additive,
wherein the first additive includes zinc cyanurate.

2. The epoxy resin composition as claimed in claim 1, wherein the zinc cyanurate is included in the epoxy resin composition in an amount of 0.01 wt % to 15 wt %, based on a total weight of the epoxy resin composition.

3. The epoxy resin composition as claimed in claim 1, wherein the zinc cyanurate includes a compound represented by Formula 5:

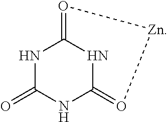

4. The epoxy resin composition as claimed in claim 1, wherein the epoxy resin includes a biphenyl type epoxy resin, a phenol aralkyl type epoxy resin, or a halogenated epoxy resin.

5. The epoxy resin composition as claimed in claim 1, wherein the curing agent includes a Xylok type phenol resin, a phenol aralkyl type phenol resin, or a phenol novolac type phenol resin.

6. The epoxy resin composition as claimed in claim 1, wherein the epoxy resin composition includes, based on a total amount of the epoxy resin composition,
2 wt % to 17 wt % of the epoxy resin,
0.1 wt % to 13 wt % of the curing agent,
50 wt % to 95 wt % of the inorganic filler,
0.01 wt % to 10 wt % of the curing catalyst, and
0.01 wt % to 15 wt % of the first additive.

7. A multichip package, the multichip package encapsulated using the epoxy resin composition as claimed in claim 1.

8. The multichip package as claimed in claim 7, wherein the zinc cyanurate is included in the epoxy resin composition in an amount of 0.01 wt % to 15 wt %, based on a total weight of the epoxy resin composition.

9. The multichip package as claimed in claim 7, wherein the zinc cyanurate includes a compound represented by Formula 5:

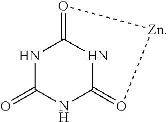

10. The multichip package as claimed in claim 7, wherein the epoxy resin includes a biphenyl type epoxy resin, a phenol aralkyl type epoxy resin, or a halogenated epoxy resin.

11. The multichip package as claimed in claim 7, wherein the curing agent includes a Xylok type phenol resin, a phenol aralkyl type phenol resin, or a phenol novolac type phenol resin.

12. The multichip package as claimed in claim 7, wherein the epoxy resin composition includes, based on a total amount of the epoxy resin composition,
2 wt % to 17 wt % of the epoxy resin,
0.1 wt % to 13 wt % of the curing agent,
50 wt % to 95 wt % of the inorganic filler,
0.01 wt % to 10 wt % of the curing catalyst, and
0.01 wt % to 15 wt % of the first additive.
